(19) United States
(12) Patent Application Publication
(10) Pub. No.: US 2022/0091049 A1
(43) Pub. Date: Mar. 24, 2022

(54) INFORMATION PROCESSING APPARATUS, LEARNING DEVICE, INFORMATION PROCESSING SYSTEM, INFORMATION PROCESSING METHOD, AND NON-TRANSITORY STORAGE MEDIUM

(71) Applicant: KONICA MINOLTA, INC., Tokyo (JP)

(72) Inventors: Ikuma OTA, Tokyo (JP); Yoshihiko EGUCHI, Tokorozawa-shi (JP)

(21) Appl. No.: 17/482,932

(22) Filed: Sep. 23, 2021

(30) Foreign Application Priority Data
Sep. 23, 2020 (JP) 2020-158289

(51) Int. Cl. G01N 23/04; G06T 7/00; G06T 7/70

(52) U.S. Cl. CPC G01N 23/04; G06T 7/0004; G06T 2207/20081; G01N 2223/401; G06T 2207/10116; G06T 7/70

(57) ABSTRACT

An information processing apparatus including a calculator configured to calculate orientation information based on a Talbot image of a sample, a structure analyzer configured to perform structural analysis of the sample based on the calculated orientation information, and an output configured to output a result of the structural analysis. The information processing apparatus may further include a learning device configured to perform part of a process of structural analysis using machine learning. The learning device may include a first learning unit that undergoes learning by associating sample manufacture information of samples with Talbot images. The learning device may include a second learning unit that undergoes learning by associating sample manufacture information of samples with a set of orientation information.

### CROSS-REFERENCE STATEMENT

The present application claims priority under 35 U.S.C. § 119 to Japanese Patent Application No. 2020-158289, filed Sep. 23, 2020, the contents of which are incorporated herein by reference in their entirety.

### BACKGROUND

### Technical Field

The disclosure relates to an information processing apparatus, a learning device, an information processing system, an information processing method, and a non-transitory storage medium.

### Description of Related Art

Composites have been attracting attention in recent years. Members made from composite material have mechanical properties that are affected not only by the quality of material but by the fine internal structure of the material. For example, carbon-fiber-reinforced plastics (CFRPs) have a three-dimensional internal structure that depends on the way carbon fiber is weaved or oriented. The mechanical strength of a CFRP is significantly affected by the fiber orientation and fiber density.

Computer-aided-engineering (CAE) systems capable of evaluating the performance of a designed product and the like through simulation are widely used. To give an example, CAE systems are utilized for analyzing the strength of a structural component that has been designed, the strength of individual materials that are to be used, or the like. Using a CAE system can eliminate labor involved in carrying out field tests and can facilitate structural optimization and so on, reducing the development cost or development time or both.

Fiber-reinforced resin as a composite requires structural analysis that takes into consideration an orientation of the fiber. A conventional strength analysis method that shows high consistency with experimental values is available. In the conventional strength analysis method (see for example Japanese Patent No. 4574880, Patent Literature 1), coupled analysis involving the following steps is performed. First, simulations for flow analysis, pressure holding and cooling analysis, and fiber orientation analysis are carried out so that fiber orientation information (for example, a fiber orientation tensor) is obtained as an analytical result. Second, structural analysis that reflects the analytical result is carried out in a consolidated manner. However, depending on a combination of factors such as composite material, fiber material, a fiber length, and so on, there are cases where the conventional strength analysis method does not yield results that are consistent with experimental results.

### SUMMARY

### Technical Problem

In order to improve the accuracy of strength analysis by the coupled analysis, a step (called validation) is necessary to verify whether the fiber orientation information, an intermediate product, obtained through the flow analysis agrees with an actual measurement. There are means to gain fiber orientation information of a real sample that covers the sample extensively. However, such means involve polishing the sample and observing the internal structure of the sample destructively using a scanning electron microscope (SEM), an optical microscope, or the like. Such a destructive observation has an effect on the sample surface that cannot be removed. Furthermore, in order to gain an understanding of the internal structure of the sample, a three-dimensional image reconstruction means such as computed tomography (CT) is necessary. However, because a large number of images need to be reconstructed, inspection takes time. Yet further, because the workpiece needs to be rotated, inspection of objects such as a large-sized component or large plate material is difficult to achieve. A method of inspecting composites that performs inspection in a short period of time that can be used to inspect large components is required. Validation requires cutting a sample into an adequate size for observation and making multiple observations to observe different parts of the sample. Validation therefore requires a significant amount of workload.

### Solution to Problem

An information processing apparatus according to a first aspect of the disclosure includes an input and a hardware processor. The input is configured to input sample manufacture information of a sample. The hardware processor is configured to predict a Talbot image based on the sample manufacture information of the sample after having undergone learning as a learning unit by associating sample manufacture information of samples with Talbot images. The hardware processor is further configured to calculate, as a calculator, orientation information of the sample based on the predicted Talbot image.

According to a third aspect of the disclosure, an information processing apparatus includes an input and a hardware processor. The input is configured to input sample manufacture information of a sample. The hardware processor is configured to predict orientation information of the sample after having undergone learning, as a learning unit, by associating sample manufacture information of samples with a set of orientation information obtained based on Talbot images. The hardware processor is configured to calculate, as a calculator, the predicted orientation information of the sample.

According to a fifth aspect of the disclosure, an information processing apparatus includes: a hardware processor; and an output. The hardware processor is configured to obtain orientation information based on a Talbot image of a sample. Furthermore, the hardware processor is configured to perform, as a structure analyzer, structural analysis of the sample based on the orientation information. The output is configured to output a result of the structural analysis.

According to a sixth aspect of the disclosure, a non-transitory computer readable storage medium storing instructions that, when executed, cause at least one hardware processor to perform an operation as a learning device. The learning device includes a first learning unit, a second learning unit, or both the first learning unit and the second learning unit. The first learning unit is configured to: obtain sample manufacture information of a sample; obtain a Talbot image obtained by imaging the sample with an X-ray Talbot imaging apparatus; and learn by associating the sample manufacture information of the sample with the Talbot image. The second learning unit is configured to: obtain the sample manufacture information of the sample; obtain the Talbot image obtained by imaging the sample with the X-ray Talbot imaging apparatus; obtain orientation information based on the Talbot image; and learn by associating the sample manufacture information of the sample with the orientation information.

According to an eighth aspect of the disclosure, an information processing method of an information processing apparatus includes: calculating orientation information based on a Talbot image of a sample; performing structural analysis of the sample based on the calculated orientation information; and outputting a result of the structural analysis.

### BRIEF DESCRIPTION OF DRAWINGS

The advantages and features provided by one or more embodiments of the disclosure will become more fully understood from the detailed description given hereinbelow and the appended drawings. The drawings are given for the purpose of illustration only and are not intended as a definition of the limits of the disclosure.

FIG. 1 is a schematic diagram of an information processing system according to one or more embodiments.

FIG. 2 is a flow chart of a process of a coupled analysis in accordance with a Comparative Example.

FIG. 3 is a flow chart of a process in accordance with a First Embodiment.

FIG. 4 is a schematic diagram of a sample.

FIG. 5 is a schematic diagram of a first Talbot image.

FIG. 6 is a schematic diagram of first Talbot orientation information.

FIG. 7 is a schematic diagram of a structural analysis model.

FIG. 8 is a graph showing a distribution of a two-dimensional scattering function.

### DETAILED DESCRIPTION OF EMBODIMENTS

Hereinafter, one or more embodiments of the disclosure will be described with reference to the drawings. However, the scope of the disclosure is not limited to the disclosed embodiments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In the following detailed description, an “image” refers to image data unless there are exceptional circumstances.

An object of the disclosure is to reduce the validation workload of sample analysis.

According to the disclosure, the workload of validating sample analysis is reduced.

### First Embodiment

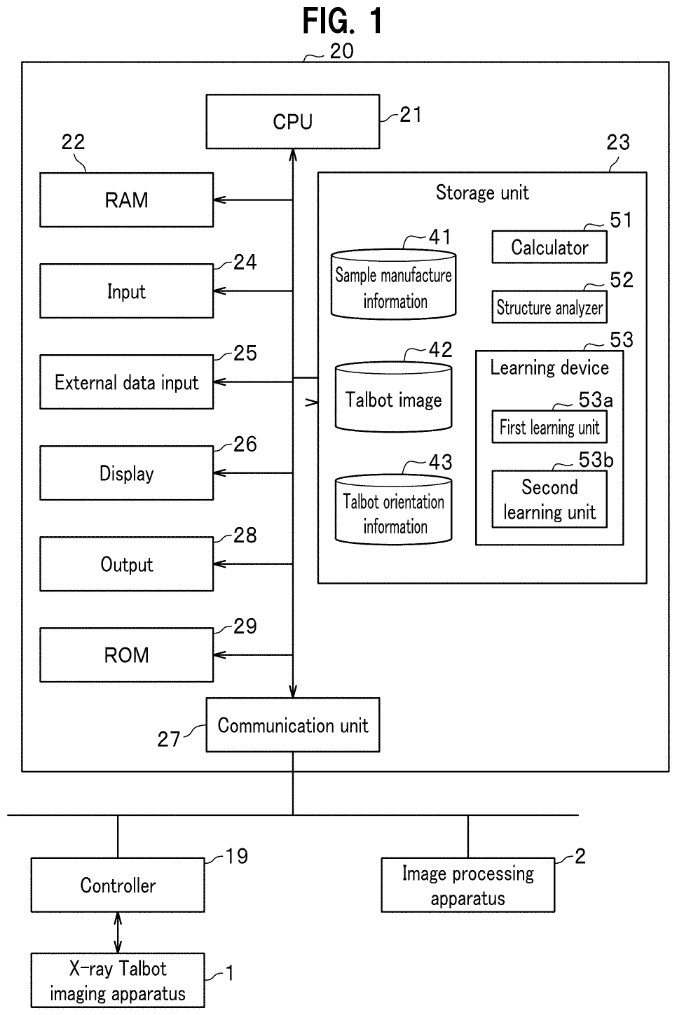

As shown in FIG. 1, an information processing system according to one or more of the present embodiment includes an X-ray Talbot imaging apparatus 1, a controller 19, an image processing apparatus 2, and a control apparatus 20. The X-ray Talbot imaging apparatus 1, the controller 19, the image processing apparatus 2, and the control apparatus 20 are communicably connected to each other via, for example, a bus.

The information processing system according to the present embodiment includes at least an X-ray Talbot imaging apparatus 1 and a control apparatus 20. An apparatus that is formed from a combination of the control apparatus 20 and image processing apparatus 2 is an example of an “information processing apparatus” of the disclosure. The control apparatus 20 can make up a part or a whole of the “information processing apparatus”.

### X-Ray Talbot Imaging Apparatus

The X-ray Talbot imaging apparatus 1 uses a Talbot-Lau interferometer that includes a source grating (also referred to as a multi-grating, multi-slit, a G0 grating, or the like). In one or more embodiments, the X-ray Talbot imaging apparatus 1 uses a Talbot interferometer that includes a G1 grating and G2 grating but not a source grating. Since a configuration and function of the X-ray Talbot imaging apparatus 1 are disclosed, for example, in Reference Literature 1 (US Patent Application Publication No. US 2019/0317027 A1, publication date Oct. 17, 2019), detailed description is omitted.

The X-ray Talbot imaging apparatus 1 can reconstruct at least three types of images (two-dimensional images) as reconstructed images by capturing a moire image of an object based on a principle of a fringe scanning method or by analyzing a moire image using a Fourier transform method. The reconstructed images are an absorption image, a differential phase image, and a small-angle scattering image.

An absorption image is an image rendered from an average component of moire fringes in a moire image and is the same as a normal X-ray absorption image.

A differential phase image is an image rendered from phase information of moire fringes.

A small-angle scattering image is an image rendered from visibility of moire fringes.

The X-ray Talbot imaging apparatus 1 can generate various types of images by recomposing an image using one or more of these three types of images.

The fringe scanning method obtains a high-definition reconstructed image by performing image reconstruction using moire images that have been captured M number of times. The moire images are captured by shifting one of multiple gratings by 1/M of a slit period of the grating in a direction of the slit period M number of times (M is a positive integer; M>2 for an absorption image; M>3 for a differential phase image or a small-angle scattering image).

The Fourier transform method involves capturing a single moire image in the presence of an object with the X-ray Talbot imaging apparatus 1. During image processing, a Fourier transform or the like is used to process the moire image to reconstruct and generate an image such as a differential phase image.

One example of an object whose image is captured by the X-ray Talbot imaging apparatus 1 is a composite (also referred to as a composite material). A composite material is a material in which two or more different materials are integrally combined and refers to a material in which at least two materials are present as phases. Materials such as alloys and ceramics made by mixing ingredients to form a single material are therefore not composite materials. Composite materials are used as constituent components of various products and so on such as spacecrafts, aircrafts, automobiles, ships, fishing rods, electric and electronic components, components in home appliances, parabolic antennae, bathtubs, floor materials, and roofing materials.

Known composite materials include fiber-reinforced plastics (FRPs), which use carbon fiber or glass fiber as reinforcing fiber, and ceramic matrix composites (CMCs), which use ceramic fiber as a reinforcing material. FRPs include carbon-fiber-reinforced plastics (CFRP), carbon-fiber reinforced-thermoplastics (CFRTPs), and glass-fiber reinforced plastics (GFRPs). More broadly, composites such as plywood that are made of a plurality of different types of wood may be included. Furthermore, composite materials such as metal matrix composites (MMC), concrete, and reinforced concrete that do not contain fiber may also be included.

Examples of resin used in composite materials include, but are not limited to, commodity plastic, engineering plastic, and super engineering plastic. Resin is used in the form of resin composite materials that have been added with a filler and are often used as molded plastic products. A filler used in resin composite materials has a micro- or nano-size structure and is added for the purpose of adding a predetermined property such as strength. Fillers include organic materials, inorganic materials, magnetic materials, and metallic materials. For example, when a molded plastic product needs to have strength or rigidity, a composite material made of resin such as polypropylene (PP), polyamide (PA), polyphenylene sulfide (PPS), or polyoxymethylene (POM) and a filler such as glass fiber (GF), aramid fiber, or mika may be used. For example, when a molded plastic material needs to be thin, a composite material made of liquid crystal polymer and GF is sometimes used. For example, when a molded plastic material is a plastic magnet, a composite material made of nylon resin and a filler such as strontium ferrite or samarium cobalt is often used.

### Controller

The controller 19 performs overall control of the X-ray Talbot imaging apparatus 1. For example, the controller 19 may set the tube voltage, tube current, irradiation time, or the like of an X-ray source of the X-ray Talbot imaging apparatus 1. For example, the controller 19 may relay signals and data transmitted between an X-ray detector of the X-ray Talbot imaging apparatus 1 and the image processing apparatus 2 or another apparatus. The controller 19 functions as a control unit to capture a series of images for obtaining multiple moire images (a single moire image in the case of a Fourier transform method) that are used to generate a reconstructed image of an object.

### Control Apparatus

The control apparatus 20 may for example be a general-purpose computer (a control PC) but is not limited to this. A part of the function of the control apparatus 20 may be provided over a network so that execution of individual processes involve data communication across the network when sending or receiving data.

As shown in FIG. 1, the control apparatus 20 includes a central processing unit 21 (a CPU 21), random-access memory 22 (RAM 22), a storage unit 23, an input 24, an external data input 25, a display 26, a communication part 27, and an output 28, read-only memory 29 (ROM 29). The input 24 and external data input 25 are examples of an “input” that one or more of the claims refer to.

The CPU 21 retrieves various types of programs such as a system program and processing program that are stored in the storage unit 23, places them into RAM 22, and executes various types of processes in accordance with the retrieved programs.

In various types of processes that are executed and controlled by the CPU 21, the RAM 22 functions as a work area for temporarily storing various types of programs that have been retrieved from the storage unit 23 and are executable by the CPU 21, input or output data, parameters, and so on.

The storage unit 23 is configured from a hard disk drive (an HDD), semiconductor non-volatile memory, or the like. In the storage unit 23, the various types of programs mentioned above and various types of data are stored.

The input 24 is configured to include a keyboard and a pointing device such as a mouse. The keyboard is equipped with keys including cursor keys, numeral input keys, and various function keys. The input 24 outputs a signal such as a signal generated from a key being pressed on the keyboard or a mouse operation signal to the CPU 21 as an input signal. The CPU 21 may execute various types of processes based on an operation signal from the input 24.

The external data input 25 is used to input data obtained from an externally provided device (including the controller 19) to the information processing system. One or more of a variety of data input means may be adopted as the external data input 25. Examples of a data input means are a Universal Serial Bus (USB) port capable sending and receiving data to and from an externally provided device over a wire or wirelessly, Bluetooth (a registered trademark), and a drive that reads data from a non-transitory storage medium corresponding to an externally provided device.

The display 26 is configured to include a monitor such as a cathode-ray tube monitor (a CRT monitor) or a liquid crystal display (an LCD). The display 26 displays various types of screens according to an instruction coming from a display signal inputted from the CPU 21. When the display 26 is a touch panel, the display 26 also includes a function of the input 24.

The communication unit 27 is equipped with a communication interface and communicates with an externally provided device in a network. The communication unit 27 may also be used the external data input 25 described above.

The output 28 outputs a result of a predetermined information processing. The predetermined information processing may for example be but is not limited to structural analysis of a structure analyzer 52 described later in the description. In cases where the outputted result is an image, the display 26 may be used to output the result.

The ROM 29 is a non-transitory storage medium for various types of programs stored in the storage unit 23. Instead of ROM 29, the non-transitory storage medium may be an above-mentioned non-transitory storage medium corresponding to an externally provided device.

### Image Processing Apparatus

The image processing apparatus 2 performs image processing of output data from the X-ray Talbot imaging apparatus 1 and sends an image that has undergone image processing to the control apparatus 20. The display 26 may display the image received from the image processing apparatus 2.

The storage unit 23 stores, for example, sample manufacture information 41, a Talbot image 42, Talbot orientation information 43, a calculator 51, a structure analyzer 52, and a learning device 53 as shown in FIG. 1. Note that the image processing apparatus 2 functions as an image processing unit. The calculator 51, structure analyzer 52, and learning device 53 are, for example, implemented as a program, and functions when the program is read and executed by the CPU 21. The Talbot orientation information 43 is an example of the “orientation information” that one or more of the claims refer to.

The sample manufacture information 41 is information regarding a sample of a composite material that is an object to be imaged by the X-ray Talbot imaging apparatus 1. The sample manufacture information 41 may for example be, but is not limited to, a sample material, a molding condition, or both. Information regarding sample material may include but is not limited to a grade, condition of an additive, or both. Information regarding a molding condition of the sample may include but is not limited to a condition on temperature, condition on injection speed, and/or condition on holding pressure.

The Talbot image 42 is an image generated by a Talbot effect when imaging of a sample is performed with the X-ray Talbot imaging apparatus 1. An image obtained by the image processing apparatus 2 performing image processing on output data of the X-ray Talbot imaging apparatus 1 is also included as a Talbot image 42.

The Talbot effect is a phenomenon in which X-rays emitted downwards from an X-ray source of the X-ray Talbot imaging apparatus 1 pass through a G1 grating and form self images (grating images) at regular distances in the vertical direction. Reconstructed images such as an absorption image, a differential phase image, and a small-angle scattering image that are reconstructed from a moire image are images generated by a Talbot effect and are therefore Talbot images 42.

Note that the term “Talbot effect” not only refers to a Talbot effect by a Talbot interferometer but also refers to a combined effect of a Talbot effect and Lau effect (obtained with the use of a G0 grating) by a Talbot-Lau interferometer.

The Talbot orientation information 43 is orientation information that is obtained from a Talbot image 42. Note that orientation information is information that indicates an orientation of fiber of a sample.

The calculator 51 calculates Talbot orientation information 43 based on a Talbot image 42.

The structure analyzer 52 performs structural analysis of a sample based on Talbot orientation information 43. The output 28 may output a result of the structural analysis of the structure analyzer 52. The result of structural analysis may for example be, but is not limited to, at least one of tensile strength, stress distribution, or warpage of the sample.

The learning device 53 is a learning model for performing structural analysis of a sample with predetermined machine learning. The learning device 53 includes a first learning unit 53a and a second learning unit 53b. The first learning unit 53a and second learning unit 53b are examples of a “learning unit” that one or more of the claims refer to.

The first learning unit 53a is a learner that has undergone learning by associating sample manufacture information 41, which is to be an input, with a Talbot image 42, which is to be an output.

The second learning unit 53b is a learner that has undergone learning by associating sample manufacture information 41, which is to be an input, and Talbot orientation information 43, which is to be an output.

### Coupled Analysis of Comparative Example

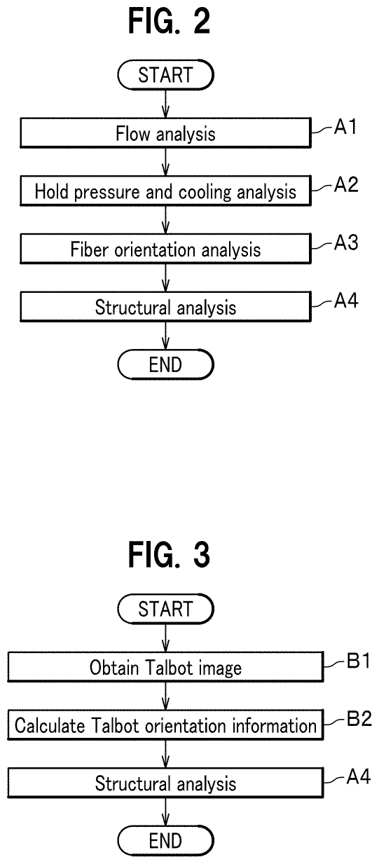

Coupled analysis of a Comparative Example will now be described with reference to FIG. 2. In the Comparative Example, a molded item that has been made from fiber reinforced resin (a composite material) through injection molding is used. Coupled analysis of the molded item performed with a CAE system proceeds as follows. The coupled analysis of the Comparative Example is, for example, described in Patent Literature 1 and follows the steps of Patent Literature 1.

First, a computer performs flow analysis using the following data to analyze flow of resin and fiber that are poured into a mold in injection molding (Step A1): data on the mold used in injection molding, data on the resin, and data on the fiber. Next, the computer performs pressure holding and cooling analysis using data on the molded item to analyze the pressure holding and cooling of the molded item (Step A2). Next, the computer performs fiber orientation analysis using data on a cooled molded item to analyze the fiber orientation of the cooled molded item (Step A3).

Finally, the computer performs structural analysis using a result of the fiber orientation analysis as input information (Step A4). The computer performs the analysis by mapping the fiber orientation information (the result of the fiber orientation analysis) onto a structural analysis model that includes shape data that is the same as the molded item. As a result of the structural analysis, a result of strength analysis such as tensile strength, stress distribution, or warpage of the molded item is obtained.

The coupled analysis of the Comparative Example is a series of analyses that takes into consideration interaction between multiple fields (such as fluid and structure). However, the coupled analysis of the Comparative Example requires validation of the fiber orientation information to improve the accuracy of the result of strength analysis that adds a significant amount of labor and burden. Actual measurements of fiber orientation information that are necessary for the validation of fiber orientation information are obtained by performing orientation information analysis using an optical microscope, an SEM, or a microfocus CT.

Orientation information analysis using an optical microscope or SEM involves observing a surface state of an observed portion of a sample in a way that causes damage to the sample. Due to the destructiveness of this observation technique, it is difficult to exclude the effect of the observation on the sample surface.

The microfocus CT is a technology that performs magnified imaging using X-ray CT. Orientation information analysis using microfocus CT is a method whereby a difference in the X-ray absorption of a filler is visualized in a three-dimensional manner by using a voxel size that is less than or equal to the size of a filler structure (e.g., a few micro-meters). In cases where the difference in X-ray absorption between resin and the filler (sensitizer) is small (e.g., in the case of CFRPs), it is difficult to obtain a contrast and thus difficult to make an observation with this method. Furthermore, because magnified imaging is involved, the shooting range of a sample that is commonly used is a few millimeter (mm) squared. To gain overall orientation information of a sample whose size is greater than 10 mm, images must be captured multiple times, requiring time and effort.

### Process

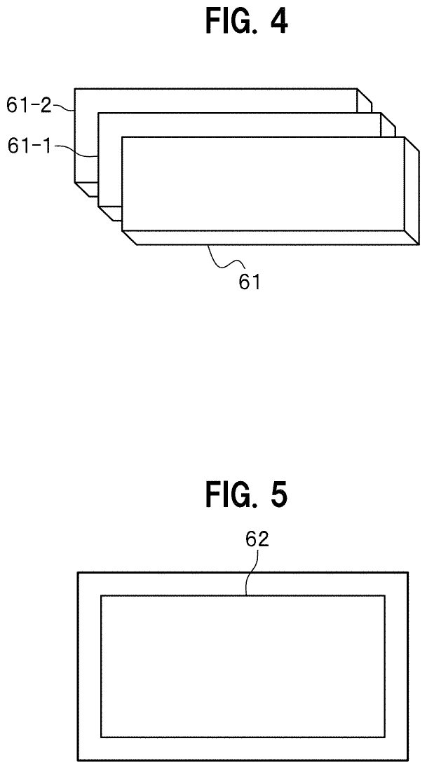

A process of the present embodiment is described with reference to FIG. 3 (and to other figures as deemed appropriate). The process for a molded item made by injection molding fiber-reinforced resin (a composite material) follows the steps given below. It should be noted that imaging of a sample, which is a molded item, using the X-ray Talbot imaging apparatus 1 has taken place prior to step B1. FIG. 4 shows a schematic diagram of three samples. Samples 61, 61-1, and 61-2 are molded items that have the same shape but have each been made using a different composite material, molding condition, or the like. The process of FIG. 3 may be carried out for each of the samples 61, 61-1, and 61-2. The process of FIG. 3 is described below using a case where sample 61 is used.

In Step B1, the control apparatus 20 obtains a Talbot image 42 from either the X-ray Talbot imaging apparatus 1 or image processing apparatus 2. FIG. 5 shows a schematic diagram of a first Talbot image 62 (a specific example of a Talbot image 42) of sample 61. Although in FIG. 5 the first Talbot image 62 is shown two-dimensionally, a three-dimensional Talbot image may be captured.

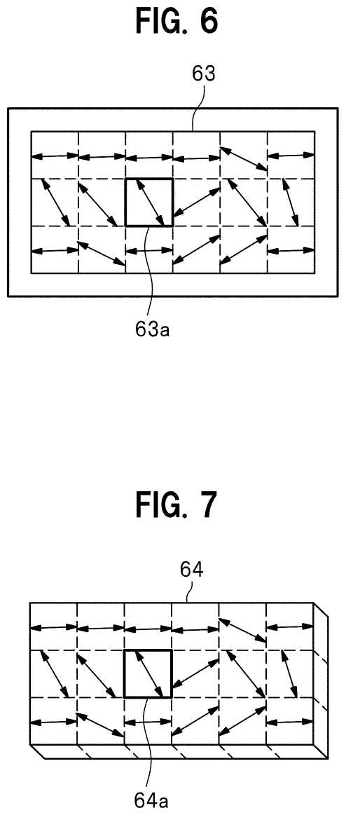

Next, in Step B2, the calculator 51 of the control apparatus 20 calculates Talbot orientation information 43 based on the Talbot image 42. FIG. 6 shows a schematic diagram of first Talbot orientation information 63 (a specific example of Talbot orientation information 43) of the sample 61. As shown in FIG. 6, the first Talbot orientation information 63 uses a mesh to divide a predetermined region into mesh elements and indicates a main orientation component of fiber for each mesh element with a double arrow (details given later). A dimension of a mesh element may range between (i) a minimum dividing unit approximately between several tens of micrometers to a hundred and several tens of micrometers as determined by a pixel size and (ii) approximately several millimeters corresponding to a plurality of the pixel size. Note that the Talbot orientation information 43 is equivalent, or an appropriate design change is made to become equivalent, to the fiber orientation information resulting from fiber orientation analysis of the coupled analysis of the Comparative Example. In cases where the first Talbot image 62 is two-dimensional, the first Talbot orientation information 63 is also two-dimensional.

Finally, in Step A4, the structure analyzer 52 of the control apparatus 20 performs the structural analysis that has been described above using the Talbot orientation information 43 as input information. FIG. 7 shows a schematic diagram of a first structural analysis model 64 (a specific example of the structural analysis model). The first structural analysis model 64 is a model in which a predetermined region has been divided with a mesh so that a mapping with the first Talbot orientation information 63 is possible. The first structural analysis model 64 is configurable using known art. The structure analyzer 52 maps the Talbot orientation information 43 on to a structural analysis model that has the same shape data as the molded item (for example, orientation information 63a of a mesh element of FIG. 6 is reflected in a corresponding mesh element 64a of FIG. 7) and performs analysis. As a result of the structural analysis, a result of strength analysis such as tensile strength, stress distribution, or warping of the molded item may be obtained.

The first structural analysis model 64 is a three-dimensional model. By assuming that a fiber direction is uniform across a direction of thickness when inputting two-dimensional first Talbot orientation information 63 to the first structural analysis model 64, structural analysis becomes possible. When a three-dimensional Talbot image and three-dimensional Talbot orientation information are inputted to the first structural analysis model 64, the abovementioned assumption is unnecessary.

The display 26 can display the first Talbot image 62, first Talbot orientation information 63, first structural analysis model 64, and result of structural analysis.

### Details of Imaging by X-Ray Talbot Imaging Apparatus 1

Imaging of a sample with the X-ray Talbot imaging apparatus 1 involves orientation imaging. Orientation imaging refers to imaging in which the relative angle between the gratings and a sample (an object that is imaged; a molded item) is changed by rotating an object-placing stage of the X-ray Talbot imaging apparatus 1 that functions as a rotating stage. Through orientation imaging, a direction in which a signal value becomes strongest for each pixel may be determined with arithmetic processing.

### Details of Talbot Orientation Information 43

The Talbot orientation information 43 that is calculated by the calculator 51 based on a Talbot image 42 is described in detail (Steps B1 and B2 of FIG. 3).

Beforehand, during orientation imaging with the X-ray Talbot imaging apparatus 1, imaging of the sample is carried out using different relative angles between the sample and the gratings. At least three different relative angles are used (e.g., 0°, 60°, and 120°; selected relative angles). Each of the selected relative angles may be achieved, for example, by rotating the sample while keeping the apparatus side fixed or by rotating the apparatus side while keeping the sample fixed. The following description uses two-dimensional imaging as an example but may be extended to three-dimensional imaging as well.

Next, a Talbot image is obtained at each of the selected relative angles. Here, at least one of the absorption image, differential phase image, or small-angle scattering image may be obtained. In the following description, a small-angle scattering image or a small-angle scattering image divided by an absorption image is used. A small-angle scattering image divided by an absorption image may be viewed as an image whose thickness dependence has been cancelled in cases where a sample has an uneven surface. For convenience of explanation, a small-angle scattering image and a small-angle scattering image divided by an absorption image are collectively referred to as a “small-angle scattering image”.

Next, the small-angle scattering images (at least three) that have been obtained at the selected relative angles are aligned. Here, because the sample has been rotated, an operation to return the images to a predetermined angle is performed.

Next, for each pixel, fitting is performed with a sine wave and a fitting parameter is extracted. The graph of the sine wave has an x-axis that represents a relative angle between the sample and the gratings and a y-axis that represents a small-angle scattering signal value of a pixel. The amplitude, average value, and phase of the sine wave are obtained as fitting parameters. An image showing amplitude values of individual pixels is referred to as an “amp image”. An image showing average values of individual pixels is referred to as an “ave image”. An image showing phases of individual pixels is referred to as a “pha image”. The amp image, ave image, and pha image are collectively referred to as an “orientation image”.

Finally, an averaging process is performed in 1 mm squared regions of the pha image to obtain main orientation information.

An orientation image depicts orientations of resin and fiber of a material of a molded item. The main orientation information is information showing a collection of main orientation components of the fiber for individual regions (corresponding to mesh elements) of a predetermined mesh of the pha image. For example, the calculator 51 may use the main orientation information as Talbot orientation information 43 so that the main orientation information is used as input information for a structural analysis model described in a later paragraph.

### Alternative Representation of Talbot Orientation Information 43 (First Example)

As mentioned above, the main orientation information may be used as input information for a structural analysis model. However, when a structural analysis model allows an orientation tensor to be used as input information, the calculator 51 may convert a Talbot image 42 to an orientation tensor. In other words, an orientation tensor may be used to represent Talbot orientation information 43.

For example, a two-dimensional orientation p of the fiber for each pixel may be described by the following expression. Angle θ represents an angle from the x-axis.

$$\begin{matrix}[ Formula 1 ] & \\ p = ( \begin{matrix}cos θ \\ sin θ\end{matrix} ) & Equation 1\end{matrix}$$

When n number of two-dimensional orientations exist in a region, the average state of orientations in that region may be defined using a two-dimensional orientation tensor A as shown below in Equation 2.

$$\begin{matrix}[ Formula 2 ] & \\ A = ( \begin{matrix}〈 {p}_{1} {p}_{1} 〉 & 〈 {p}_{1} {p}_{2} 〉 \\ 〈 {p}_{2} {p}_{1} 〉 & 〈 {p}_{2} {p}_{2} 〉\end{matrix} ) = ( \begin{matrix}\frac{1}{n} \sum {p}_{1} {p}_{1} & \frac{1}{n} \sum {p}_{1} {p}_{2} \\ \frac{1}{n} \sum {p}_{1} {p}_{2} & \frac{1}{n} \sum {p}_{2} {p}_{2}\end{matrix} ) & Equation 2\end{matrix}$$

Here, the sum of diagonal components of the two-dimensional orientation tensor is 1 (trace A=1). Also, p₁ and p₂ of Equation 2 are values of p when θ of Equation 1 takes different values.

For example, the calculator 51 may use the orientation tensor as Talbot orientation information 43 so that the orientation tensor is used as input information for the structural analysis model described in a later paragraph.

### Alternative Representation of Talbot Orientation Information 43 (Second Example)

The above-mentioned main orientation information may be used as input information for a structural analysis model. However, when a structural analysis model allows a tensor representation of a two-dimensional scattering function to be used as input information, the calculator 51 may convert a Talbot image 42 into a tensor representation of a two-dimensional scattering function. In other words, the tensor representation of a two-dimensional scattering function may be used to represent Talbot orientation information 43. The explanation of this follows Reference Literature 2 (Directional x-ray dark-field imaging of strongly ordered systems, PHYSICAL REVIEW B 82, 214103 [2010]).

According to Reference Literature 2, when a two-dimensional scattering function μ(x, y) of a scatterer spread across between the x- and y-axes is considered using a Gaussian function model, the two-dimensional scattering function may be described using Equation 3 given below.

$$\begin{matrix}[ Formula 3 ] & \\ μ ( x , y ) = \frac{1}{2 π {σ}_{1} {σ}_{2}} exp ( - ( {ax}^{2} + bxy + {cy}^{2} ) ) ) \\ a = \frac{{cos}^{2} {θ}_{0}}{2 {σ}_{1}^{2}} + \frac{{sin}^{2} {θ}_{0}}{2 {σ}_{2}^{2}} \\ b = sin {θ}_{0} cos {θ}_{0} ( - \frac{1}{2 {σ}_{1}^{2}} + \frac{1}{2 {σ}_{2}^{2}} ) \\ c = \frac{{sin}^{2} {θ}_{0}}{2 {σ}_{1}^{2}} + \frac{{cos}^{2} {θ}_{0}}{2 {σ}_{2}^{2}} & Equation 3\end{matrix}$$

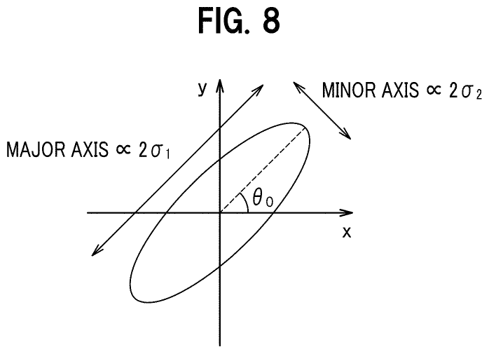

Here, σ₁ and σ₂ are indices indicating the anisotropy of scattering in magnitude-specific directions of principal-axis components of a Gaussian function. For a scatterer such as fiber, the values of σ₁ and σ₂ become large. For this reason, a ratio of σ₁ and σ₂ may be used as an index of anisotropy. As shown in FIG. 8, the ratio of a major axis and a minor axis when a contour of a scatter function is drawn is 2σ₁:2σ₂, and this ratio can be used as an index of anisotropy. Furthermore, θ₀ as indicated in FIG. 8, is the angle between σ₁ and the x axis. For example, when the distribution of fiber orientations spread across an x-y space shows that many of the individual fibers are inclined at angle of 45 degrees with respect to the x-axis, then θ₀=45.

Equation 4 below shows a tensor representation U of the scattering function with a, b, and c representing components of the tensor.

$$\begin{matrix}[ Formula 4 ] & \\ U = ( \begin{matrix}a & b \\ b & c\end{matrix} ) & Equation 4\end{matrix}$$

The small-angle scattering image obtained from Talbot image capturing may be expressed in terms of θ, a relative angle between the gratings and a scatterer, as shown in Equation 5 below. k is a constant determined by the grating period.

[Formula 5]

V(θ)=exp(−k(σ₁²+σ₂²))exp(−k(σ₁²−σ₂²)cos(2(θ−θ₀)−π) Equation 5

By applying logarithmic transformation and adding a negative sign to Equation 5 (so that the equation becomes more interpretable), Equation 6 is obtained.

[Formula 6]

SC(θ)=−ln V=k(σ₁²+σ₂²)−k(σ₁²−σ₂²)cos(2(θ−θ₀)) Equation 6

By capturing an image of a sample multiple times during the Talbot image capturing process using different relative angles between the sample and gratings, it becomes possible to calculate a maximum value (max) of SC(θ), a minimum value (min) of SC(θ), and an angle θ₀ when SC(θ) is the largest (see Equation 7). (This is similar to the procedure for extracting an orientation image described above.)

$$\begin{matrix}[ Formula 7 ] & \\ max = SC ( {θ}_{0} ) = 2 k {σ}_{2}^{2} \\ min = SC ( {θ}_{0} + \frac{1}{2} π ) = 2 k {σ}_{1}^{2} & Equation 7\end{matrix}$$

Next, by applying the information obtained from Talbot image capturing to the tensor representation U of a two-dimensional scattering function, Equation 8 is obtained.

$$\begin{matrix} [ Formula 8 ] & \\ U = k ( \begin{matrix}\frac{{cos}^{2} {θ}_{0}}{max} + \frac{{sin}^{2} {θ}_{0}}{min} & sin {θ}_{0} cos {θ}_{0} ( - \frac{1}{max} + \frac{1}{min} ) \\ sin {θ}_{0} cos {θ}_{0} ( - \frac{1}{max} + \frac{1}{min} ) & \frac{{sin}^{2} {θ}_{0}}{max} + \frac{{cos}^{2} {θ}_{0}}{min}\end{matrix} ) & Equation 8\end{matrix}$$

The two-dimensional scattering function expresses a spatial distribution of a scattering image. Therefore, the two-dimensional scattering function is considered to correspond to an orientation tensor of fiber orientation analysis. Here, the sum of diagonal components of the orientation tensor of fiber orientation analysis is defined as one. Normalizing the tensor representation U of the two-dimensional scattering function by the diagonal components results in Uₙₒᵣₘ as defined by Equation 9.

$$[ Formula 9 ]$$

$$Equation 9$$

$${U}_{norm} = {k}_{norm} ( \begin{matrix}\frac{{cos}^{2} {θ}_{0}}{min} + \frac{{sin}^{2} {θ}_{0}}{max} & sin {θ}_{0} cos {θ}_{0} ( - \frac{1}{min} + \frac{1}{max} ) \\ sin {θ}_{0} cos {θ}_{0} ( - \frac{1}{min} + \frac{1}{max} ) & \frac{{sin}^{2} {θ}_{0}}{min} + \frac{{cos}^{2} {θ}_{0}}{max}\end{matrix} )$$

$${k}_{norm} = \frac{k}{min} + \frac{k}{max}$$

For example, the calculator 51 may use the tensor representation U of the two-dimensional scattering function as Talbot orientation information 43 so that the tensor representation U is used as input information for the structural analysis model described in a later paragraph.

### Details of Structural Analysis Using Talbot Orientation Information 43

In the structural analysis described above, the structural analysis model is prepared by using a mesh to split the shape of an object under analysis into mesh elements and inputting physical property information for each mesh element (see FIG. 7). When the object under analysis is a composite, the following are input as physical property information for individual mesh elements: a physical property of resin used as base material, a physical property of fiber, and orientation information of fiber.

For example, the physical property of resin and physical property of fiber may be data of a tensile stress-strain curve. Data of the tensile stress-strain curve can be referenced from a database of a predetermined simulation.

The orientation information of fiber may be Talbot orientation information 43.

Structural analysis such as this is a known technique and can be implemented by using software such as Digimat (a product of e-Xstream engineering) and PlanetsX (a product of Ansys).

Note that the structural analysis of the present embodiment assumes that unevenness in the concentrations of resin and fiber does not exist. Therefore, values of resin and fiber concentrations that are inputted for individual mesh elements of the structural analysis model are kept the same. By using this condition, calculation load of structural analysis is reduced.

In one or more embodiments, differences in resin and fiber concentrations are considered, in which case different values of resin and fiber concentrations are inputted for individual mesh elements of the structural analysis model. This may be achieved, for example, by converting signal strength information of an absorption image of a Talbot image into degrees of concentration of the resin and by converting signal strength information of an ave image of an orientation image into degrees of concentration of the fiber.

In the structural analysis of the present embodiment, it is assumed that the resin and fiber do not shrink. Therefore, values of shrinkage strain of the fiber that are inputted for individual mesh elements of the structural analysis model are kept the same. By using this condition, calculation load of structural analysis is reduced.

In one or more embodiments, shrinkage of the resin and fiber are considered, and values of shrinkage strain of the resin and fiber that are inputted for individual mesh elements of the structural analysis model are set individually.

In one or more embodiments, with regards to the values of shrinkage strain and concentrations of resin and fiber, flow analysis and hold pressure and cooling analysis are implemented so that values obtained therefrom are used as inputted values.

### Details of Result of Structural Analysis

By applying loading data such as boundary condition data, external force, or imposed displacement as input data to a structural analysis model, response data (regarding response to the loading) such as amount of deformation data or stress data is obtained as output data. Response data is an example of a result of strength analysis. Structural analysis such as this is a known technique and can be implemented by using software such as Digimat (a product of e-Xstream engineering) and PlanetsX (a product of Ansys).

### Advantageous Effects of First Embodiment

In the coupled analysis of the Comparative Example, the fiber orientation information resulting from the fiber orientation analysis is fictitious data obtained from simulation. In contrast, a Talbot image 42 that is generated through imaging by the X-ray Talbot imaging apparatus 1 and through image processing by the image processing apparatus 2 is measured data. Therefore, Talbot orientation information 43 calculated from the Talbot image 42 is also measured data. Therefore, according to the process of FIG. 3, since the input information for the structural analysis is measured data, validation of fiber orientation information used as input information for the structural analysis is unnecessary. As a result, workload for validating analysis of a sample can be reduced.

Furthermore, because the diameter of a fiber is in the range between several μm and several tens of μm, fiber orientation analysis of a composite material not only requires a field of view that covers the entire sample whose size may be over 10 mm but requires resolution in the order of micrometers as well.

With conventional devices such as an optical microscope, an SEM, and a microfocus CT, not only is it necessary to make an observation of a magnified projection of the sample (in order to achieve resolution in the order to micrometers), but observation needs to be performed multiple times to observe different parts of the sample (in order to analyze the fiber orientation of the entire sample). In contrast, a Talbot image 42 is by principle able to obtain, in a region of approximately several tens of μm to a hundred and several tens of μm that is determined by pixel size, a signal that is proportional to the amount of fiber that is parallel to a grating orientation (a direction in which individual slits of the gratings extend). Therefore, fiber orientations over a region that is more than ten times as large compared to conventional devices can be captured. Because of this, image taking with the X-ray Talbot imaging apparatus 1 generally takes place once (although images must be captured at least three times using different relative angles between the sample and gratings, this is different to capturing images of different parts of the sample). Because an analyzed area of composite material using the X-ray Talbot imaging apparatus 1 is larger than the analyzed area using conventional devices, labor involved in sample observation can be reduced.

### Second Embodiment

The following description of a Second Embodiment omits parts that overlap with the description of the First Embodiment and focuses on the differences. With regards to the parts that overlap with the First Embodiment, the issue that can be overcome with the First Embodiment can also be overcome with the Second Embodiment. Furthermore, with regards to the parts that overlap with the First Embodiment, the advantageous effects of the First Embodiment are also achieved with the Second Embodiment.

The first learning unit 53a is used in the Second Embodiment. For example, the first learning unit 53a is, but is not limited to, a surrogate model. A surrogate model, an alternative to mathematical simulation, predicts a phenomenon using machine learning and is known art. Machine learning is, for example, a neural network, but is not limited to this. Surrogate models predict a phenomenon faster than mathematical simulation and its usage includes shape optimization and conceptual design.

A learning phase of the first learning unit 53a proceeds as follows. First, a set of samples is fabricated using the same mold. Each sample (of the set) is fabricated with a different material or molding condition or both. The used material and molding condition are stored as sample manufacture information 41 in the storage unit 23 and are also used as input data x0 for the first learning unit 53a. Note that inputting information to the first learning unit 53a is carried out by at least one of the input 24 or external data input 25.

Next, imaging of the fabricated samples are carried out with the X-ray Talbot imaging apparatus 1 and Talbot images 42 are generated. The Talbot images 42 are stored in the storage unit 23 and are also used as output data (teaching data) y0 for the first learning unit 53a. Finally, a learning model that has learned a function y0=F(x0) is generated that is used as the first learning unit 53a. F is a predetermined function used in the surrogate model and is a design factor.

A prediction phase of the first learning unit 53a proceeds as follows. It is assumed that the mold of a molded item is the same as the mold used in the learning phase. The shape of the molded item is therefore the same as the set of samples. First, a material and molding condition that have been selected for the molded item are inputted to the first learning unit 53a. Next, the first learning unit 53a predicts and generates a Talbot image.

With the above, the prediction phase is complete. After the prediction phase, the calculator 51 calculates Talbot orientation information 43 based on the predicted Talbot image. Furthermore, based on the calculated Talbot orientation information 43, the structure analyzer 52 performs structural analysis of a sample (data) corresponding to the material and molding condition that have been inputted. The output 28 outputs a result of the structural analysis performed by the structure analyzer 52.

According to the present embodiment, part of a preparatory process prior to the structural analysis is achieved using machine learning, and therefore, labor involved in obtaining a result from structural analysis can be reduced.

### Third Embodiment

The following description of a Third Embodiment omits one or more parts that overlap with the description of the First and Second Embodiments and focuses on the differences. With regards to the parts that overlap with the First Embodiment and/or Second Embodiment, the issue that can be overcome with the First Embodiment and/or Second Embodiment can also be overcome with the Third Embodiment. Furthermore, with regards to the parts that overlap with the First Embodiment and/or Second Embodiment, the advantageous effect of the First Embodiment and/or Second Embodiment are also achieved with the Third Embodiment.

The second learning unit 53b is used in the Third Embodiment. For example, the second learning unit 53b is, but is not limited to, a surrogate model. Machine learning used for the surrogate model is, for example, a neural network, but is not limited to this.

A learning phase of the second learning unit 53b proceeds as follows. First, a set of samples is fabricated using the same mold. Each sample (of the set) is fabricated with a different material or molding condition or both. The used material and molding condition are stored as sample manufacture information 41 in the storage unit 23 and are also used as input data x0 for the second learning unit 53b. Note that inputting information to the second learning unit 53b is carried out by at least one of the input 24 or external data input 25.

Next, imaging of the fabricated samples are carried out with the X-ray Talbot imaging apparatus 1 and Talbot images 42 are generated. The Talbot images 42 are stored in the storage unit 23. Next, the calculator 51 calculates Talbot orientation information 43 based on the generated Talbot images 42. The calculated Talbot orientation information 43 is stored in the storage unit 23 and is also used as output data (teaching data) y1 for the second learning unit 53b. Finally, a learning model that has learned a function y1=G(x0) is generated that is used as the second learning unit 53b. G is a predetermined function used in the surrogate model and is a design factor.

A prediction phase of the second learning unit 53b proceeds as follows. It is assumed that the mold of a molded item is the same as the mold that was used in the learning phase. The shape of the molded item is therefore the same as the set of samples. First, material and a molding condition that are selected for the molded item are inputted to the second learning unit 53b. Next, the second learning unit 53b predicts and generates Talbot orientation information. In the Third Embodiment, the calculator 51 may be used in the prediction function of the second learning unit 53b.

With the above, the prediction phase is complete. After the prediction phase, the structure analyzer 52 performs, based on the predicted Talbot orientation information, structural analysis of a sample (data) corresponding to the material and molding condition that have been inputted. The output 28 outputs a result of the structural analysis performed by the structure analyzer 52.

According to the present embodiment, part of a preparatory process prior to the structural analysis is achieved using machine learning, and therefore, labor involved in obtaining a result from structural analysis can be reduced. Especially, because a Talbot image is not necessary in the prediction phase, imaging with an X-ray Talbot imaging apparatus 1 is unnecessary, reducing labor even further.

### Variations

(a) Although the above embodiments have been described for a molded item made from injection molding, the disclosure is applicable to molded items made from press molding.

(b) Learning units are not limited to the first learning unit 53a and second learning unit 53b. Input data and output data that are associated with each other using machine learning may be altered as deemed appropriate. For example, in one or more embodiments, a learning unit may be created whose input data is sample manufacture information 41 and output data is a result of structural analysis of the structure analyzer 52. For example, in one or more embodiments, a learning unit may be created whose input data is a Talbot image 42 and output data is Talbot orientation information 43. For example, in one or more embodiments, a learning unit may be created whose input data is a Talbot image 42 and output data is a result of structural analysis of the structure analyzer 52.

For example, in one or more embodiments, a learning unit may be created whose input data is Talbot orientation information 43 and output data is a result of structural analysis of the structure analyzer 52.

(c) Various techniques of the disclosure that have been described may be combined as deemed appropriate.

### OTHER ASPECTS OF THE DISCLOSURE

According to a second aspect of the disclosure, an information processing apparatus is in accordance with the first aspect and further includes an output. The hardware processor is further configured to perform, as a structure analyzer, structural analysis of the sample based on the calculated orientation information. The output is configured to output a result of the structural analysis.

According to a fourth aspect of the disclosure, an information processing apparatus is in accordance with the third aspect and further includes an output. The hardware processor is further configured to perform, as a structure analyzer, structural analysis of the sample based on the calculated orientation information. The output is configured to output a result of the structural analysis.

According to a seventh aspect of the disclosure, an information processing system includes: an X-ray Talbot imaging apparatus; and the information processing apparatus according to the fifth aspect. The hardware processor of the information processing apparatus is further configured to obtain the Talbot image by imaging the sample with the X-ray Talbot imaging apparatus. The information processing apparatus further includes a display configured to display the Talbot image, the orientation information, a structural analysis model used in the structural analysis, and the result of the structural analysis.

According to a ninth aspect of the disclosure, a non-transitory computer readable storage medium stores instructions that, when executed, cause at least one hardware processor to perform the information processing method according to the eighth aspect.

According to a tenth aspect of the disclosure, a non-transitory computer readable storage medium stores instructions that, when executed, cause at least one hardware processor to perform an operation as a learning device. The learning device includes a learning unit that is configured to obtain sample manufacture information of a sample, obtain a Talbot image obtained by imaging the sample with an X-ray Talbot imaging apparatus, and learn by associating the sample manufacture information of the sample with the Talbot image.

According to an eleventh aspect of the disclosure, a non-transitory computer readable storage medium stores instructions that, when executed, cause at least one hardware processor to perform an operation as a learning device. The learning device includes a learning unit that is configured to obtain sample manufacture information of a sample, obtain a Talbot image obtained by imaging the sample with an X-ray Talbot imaging apparatus, obtain orientation information based on the Talbot image, and learn by associating the sample manufacture information of the sample with the orientation information.

According to a twelfth aspect of the disclosure, an information processing system includes an X-ray Talbot imaging apparatus and an information processing apparatus. The information processing apparatus includes a hardware processor, an output, and a display. The hardware processor is configured to obtain a Talbot image by imaging a sample with the X-ray Talbot imaging apparatus, obtain orientation information of the sample based on the Talbot image, and perform, as a structure analyzer, structural analysis of the sample based on the orientation information of the sample. The output is configured to output a result of the structural analysis. The display is configured to display the Talbot image, the orientation information, a structural analysis model used in the structural analysis, and the result of the structural analysis.

Although embodiments of the disclosure have been described and illustrated in detail, the disclosed embodiments are made for purposes of illustration and example only and not limitation. Modifications and variations of the embodiments described above will occur to those skilled in the art in light of the above teachings. The scope of the disclosure should be interpreted by terms of the appended claims.

What is claimed is:

1. An information processing apparatus comprising:
an input configured to input sample manufacture information of a sample; and
a hardware processor configured to
predict a Talbot image based on the sample manufacture information of the sample after having undergone learning as a learning unit by associating sample manufacture information of samples with Talbot images, and
calculate, as a calculator, orientation information of the sample based on the predicted Talbot image.

2. The information processing apparatus according to claim 1 further comprising:
an output, wherein
the hardware processor is further configured to perform, as a structure analyzer, structural analysis of the sample based on the calculated orientation information, and
the output is configured to output a result of the structural analysis.

3. An information processing apparatus comprising:
an input configured to input sample manufacture information of a sample; and
a hardware processor configured to
predict orientation information of the sample after having undergone learning, as a learning unit, by associating sample manufacture information of samples with a set of orientation information obtained based on Talbot images, and
calculate, as a calculator, the predicted orientation information of the sample.

4. The information processing apparatus according to claim 3 further comprising:
an output, wherein
the hardware processor is further configured to perform, as a structure analyzer, structural analysis of the sample based on the calculated orientation information, and
the output is configured to output a result of the structural analysis.

5. An information processing apparatus comprising:
a hardware processor configured to
obtain orientation information based on a Talbot image of a sample, and
perform, as a structure analyzer, structural analysis of the sample based on the orientation information; and
an output configured to output a result of the structural analysis.

6. A non-transitory computer readable storage medium storing instructions that, when executed, cause at least one hardware processor to perform an operation as a learning device, wherein
the learning device comprises a first learning unit, a second learning unit, or both the first learning unit and the second learning unit,
the first learning unit is configured to:
obtain sample manufacture information of a sample;
obtain a Talbot image obtained by imaging the sample with an X-ray Talbot imaging apparatus; and
learn by associating the sample manufacture information of the sample with the Talbot image, and
the second learning unit is configured to:
obtain the sample manufacture information of the sample;
obtain the Talbot image obtained by imaging the sample with the X-ray Talbot imaging apparatus;
obtain orientation information based on the Talbot image; and
learn by associating the sample manufacture information of the sample with the orientation information.

7. An information processing system comprising:
an X-ray Talbot imaging apparatus; and
the information processing apparatus according to claim 5, wherein
the hardware processor of the information processing apparatus is further configured to obtain the Talbot image by imaging the sample with the X-ray Talbot imaging apparatus, and
the information processing apparatus further includes a display configured to display the Talbot image, the orientation information, a structural analysis model used in the structural analysis, and the result of the structural analysis.

8. An information processing method of an information processing apparatus, the information processing method comprising:
calculating orientation information based on a Talbot image of a sample;
performing structural analysis of the sample based on the calculated orientation information; and
outputting a result of the structural analysis.

9. A non-transitory computer readable storage medium storing instructions that, when executed, cause at least one hardware processor to perform the information processing method according to claim 8.
